(19) United States
(12) Patent Application Publication
(10) Pub. No.: US 2025/0271495 A1
(43) Pub. Date: Aug. 28, 2025

(54) CHIP TEST SYSTEM AND METHOD

(71) Applicant: Winbond Electronics Corp., Taichung City (TW)

(72) Inventor: Chih-Chiang Lai, Hsin-Chu (TW)

(73) Assignee: Winbond Electronics Corp., Taichung City (TW)

(21) Appl. No.: 19/063,262

(22) Filed: Feb. 25, 2025

(30) Foreign Application Priority Data
Feb. 26, 2024 (TW) 113106717

(51) Int. Cl. G01R 31/28

(52) U.S. Cl. CPC G01R 31/2884

(57) ABSTRACT

A chip test system and method are provided. The chip test system includes a memory chip, a test device, and a test interface. The memory chip has a power pad and a driver pad coupled to the power pad. The test device is configured to provide a test signal. The test interface is configured to provide multiple signal transmission paths. The test device transmits the test signal to the power pad of the memory chip through the test interface, obtains a monitor voltage generated by the driver pad, and adjusts a test voltage value of the test signal according to the monitor voltage. The test device comprises a precise measurement unit configured to measure the monitor voltage, and a switch element coupled to the precise measurement unit, and when the memory chip starts to be tested, the switch element is turned on.

### CROSS-REFERENCE TO RELATED APPLICATION

This application claims the priority benefit of Taiwan application serial no. 113106717, filed on Feb. 26, 2024. The entirety of the above-mentioned patent application is hereby incorporated by reference herein and made a part of this specification.

### BACKGROUND

### Technical Field

The disclosure relates to a wafer test, and more particularly, to a chip test system and method that may reduce an impact of contact impedance.

### Description of Related Art

With the continuous advancement of process technology and the development of applications, new memory products are required to have lower voltages, higher speed and operating currents. It is foreseeable that there will be more and more memory products with smaller signal margins in the future, so that memory testing, especially the wafer-level probing for known good die (KGD), has become critical, and the cost of testing has become higher.

For memory testing, one of the key factors affecting test accuracy is an issue of voltage loss (also referred to as a voltage drop herein) caused by contact impedance between a test tool and a device under test (DUT). In addition, in actual applications, the contact impedance between the test tool and the DUT may cause variations in the voltage drop due to factors such as a test environment and contact conditions between a probe and a pad (e.g., a contact area and cumulative number of contacts), which may lead to overkilling such that a yield of a memory is reduced. Especially on a power pad, due to a larger current transmitted, an effect of the voltage drop caused by the contact impedance between the test tool and the DUT will be greater. In order to improve the issue of contact impedance between the test tool and the DUT, in the conventional technology, attention is paid to the fact that when the cumulative number of contacts between the probe and the pad increases, the contact impedance between the test tool and the DUT also increases, so it is proposed to increase the cleaning frequency of the probe. However, blindly increasing the cleaning frequency of the probe will reduce the service life of the probe, increase the test time, and significantly increase the test cost. Therefore, how to avoid reduction of the test accuracy due to the voltage drop, while maintaining test quality and productivity, and reducing the test cost has become an increasingly important issue.

### SUMMARY

The disclosure provides a chip test system and method that may compensate for a voltage drop caused by contact impedance and increase tolerance of the contact impedance.

A chip test system in the disclosure includes a memory chip, a test device, and a test interface. The memory chip has a power pad and a driver pad coupled to the power pad. The test device is configured to provide a test signal. The test interface is coupled between the memory chip and the test device to provide multiple signal transmission paths. The signal transmission paths include a first signal transmission path having first contact impedance, and a second signal transmission path having second contact impedance. The test device includes a programmable power supply coupled to the first signal transmission path to generate the test signal and measure a test current flowing through the first signal transmission path, and is configured to transmit the test signal to the power pad of the memory chip through the first signal transmission path, obtain a monitor voltage generated by the driver pad through the second signal transmission path, and adjust a test voltage value of the test signal by controlling the programmable power supply according to the monitor voltage, the first contact impedance, and the test signal.

A chip test method in the disclosure is suitable for the memory chip having a power pad and a driver pad coupled to the power pad. The chip test method includes the following. A test interface is provided to provide multiple signal transmission paths including a first signal transmission path having first contact impedance, and a second signal transmission path having second contact impedance. A test signal is generated, and a test current flowing through the first signal transmission path is measured by a programmable power supply coupled to the first signal transmission path. The test signal is transmitted to the power pad of the memory chip through the first signal transmission path. A monitor voltage generated by the driver pad is obtained through the second signal transmission path. A test voltage value of the test signal is adjusted by controlling the programmable power supply according to the monitor voltage, the first contact impedance, and the test signal.

A chip test system in the disclosure includes a memory chip, a test device, and a test interface. The memory chip has a power pad and a driver pad coupled to the power pad. The test device is configured to provide a test signal. The test interface is coupled between the memory chip and the test device to provide multiple signal transmission paths. The signal transmission paths include a first signal transmission path having first contact impedance, and a second signal transmission path having second contact impedance. The test device is configured to transmit the test signal to the power pad of the memory chip through the first signal transmission path, obtain a monitor voltage generated by the driver pad through the second signal transmission path, and adjust a test voltage value of the test signal according to the monitor voltage. The test device includes a precise measurement unit and a switch element. The precise measurement unit is coupled to the second signal transmission path to measure the monitor voltage. The switch element is coupled between the precise measurement unit and the second signal transmission path, and when the memory chip starts to be tested, the switch element is turned on.

Based on the above, the chip test system in the disclosure may monitor the voltage value of the test signal transmitted to the power pad through the driver pad on the memory chip, and adjust the test voltage value of the test signal accordingly. In this way, the voltage drop caused by the contact impedance may be appropriately compensated to avoid reduction of test accuracy due to the voltage drop, while maintaining test quality and productivity, and reducing the test cost.

### BRIEF DESCRIPTION OF THE DRAWINGS

FIG. 1 is a schematic block diagram of a chip test system according to an embodiment of the disclosure.

FIG. 2 is a schematic diagram of a chip test system according to an embodiment of the disclosure.

FIG. 3 is a schematic diagram of a chip test system according to another embodiment of the disclosure.

FIG. 4 is an example of a truth table according to an embodiment of the disclosure.

FIG. 5 is a flow chart of steps of a chip test method according to an embodiment of the disclosure.

FIG. 6 is a flow chart of steps of a chip test method according to another embodiment of the disclosure.

### DETAILED DESCRIPTION OF DISCLOSED EMBODIMENTS

In order to make the content of the disclosure easier to understand, the following specific embodiments are illustrated as examples of the actual implementation of the disclosure. In addition, elements/components/steps with the same reference numerals in the drawings and embodiments may represent the same or similar parts.

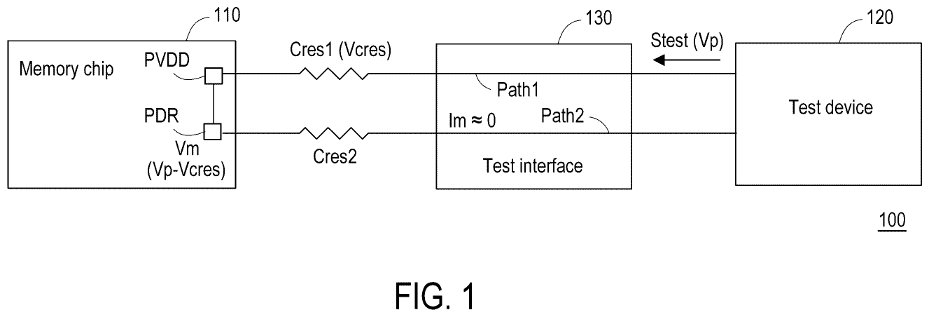

Referring to FIG. 1, a chip test system 100 includes a memory chip 110, a test device 120, and a test interface 130. The memory chip 110 is, for example, a semiconductor chip selected from a semiconductor wafer under test for testing. The semiconductor wafer may be formed by silicon or other semiconductor materials. The memory chip 110 may include a logic circuit, a memory circuit, an analog device circuit, other similar circuits, or a combination thereof, but the disclosure is not limited thereto. For example, the memory chip 110 may be a DRAM chip.

As shown in FIG. 1, the memory chip 110 has a power pad PVDD and a driver pad PDR coupled to the power pad PVDD. Materials of the power pad PVDD and the driver pad PDR are metal materials, such as aluminum, aluminum alloy, or a combination thereof. The power pad PVDD and the driver pad PDR may be interconnected with a metal circuit layer in the memory chip 110. The power pad PVDD is, for example, a pad configured to receive a power voltage, and the driver pad PDR is, for example, a pad configured to transmit a driving signal or an input/output signal. In practical applications, a pad closer to the power pad PVDD may be configured as the driver pad PDR.

The test device 120 may be configured to provide a test signal Stest. The test interface 130 includes, for example, a test tool such as a probe card, which is coupled between the memory chip 110 and the test device 120 to provide multiple signal transmission paths such as a first signal transmission path Path1 and a second signal transmission path Path2. There is first contact impedance Cres1 on the first signal transmission path Path1, and there is second contact impedance Cres2 on the second signal transmission path Path2. In the practical applications, corresponding pins of the test interface 130 may contact to the power pad PVDD and the driver pad PDR to form the first signal transmission path Path1 and the second signal transmission path Path2.

In this embodiment, the test device 120 may transmit the test signal Stest to the power pad PVDD of the memory chip 110 through the test interface 130, obtain a monitor voltage Vm generated by the driver pad PDR, and adjust a test voltage value Vp of the test signal Stest according to the monitor voltage Vm. The test voltage value Vp refers to a voltage value of the test signal Stest on a side of the test device 120, which may be regarded as the voltage value of the test signal Stest before suffering any loss (voltage drop). Specifically, in a specific test mode, the test device 120 may set the initial test voltage value Vp of the test signal Stest to be the same as a target voltage value corresponding to a current test mode. The test device 120 may transmit the test signal Stest to the power pad PVDD through the first signal transmission path Path1. The test signal Stest transmitted to the power pad PVDD will generate a voltage drop Vcres according to the first contact impedance Cres1. Therefore, a voltage received on the power pad PVDD is the test voltage value Vp minus the voltage drop Vcres. Since the driver pad PDR and the power pad PVDD have the same potential, the monitor voltage Vm generated by the driver pad PDR will also be equal to the test voltage value Vp minus the voltage drop Vcres. In this embodiment, the target voltage value is, for example, the voltage value of the test signal Stest that is preset to be transmitted to the power pad PVDD for the specific test mode.

Furthermore, the test device 120 may obtain the monitor voltage Vm through the second signal transmission path Path2. Since a monitor current Im on the second signal transmission path Path2 is substantially 0 (equal to or almost close to 0), the second contact impedance Cres2 on the second signal transmission path Path2 will not cause the voltage drop. Therefore, the test device 120 may accurately obtain the monitor voltage Vm. When the monitor voltage Vm is less than the target voltage value, the test device 120 may increase the test voltage value Vp of the test signal Stest, thereby compensating for the voltage drop Vcres caused by the first contact impedance Cres1, so that the voltage value of the test signal Stest transmitted to the power pad PVDD is equal to or close to the target voltage value. In some embodiments, the test device 120 may repeatedly increase the test voltage value Vp of the test signal Stest until the monitor voltage Vm is equal to or close to the target voltage value.

It should be noted that in this embodiment, the test mode is a mode planned in advance for various items tested by the test device 120 on the memory chip 110. Due to different test items, the target voltage value in each of the test modes is also different. In addition, the memory chip 110 may be also required to enter different states to be tested according to different test modes.

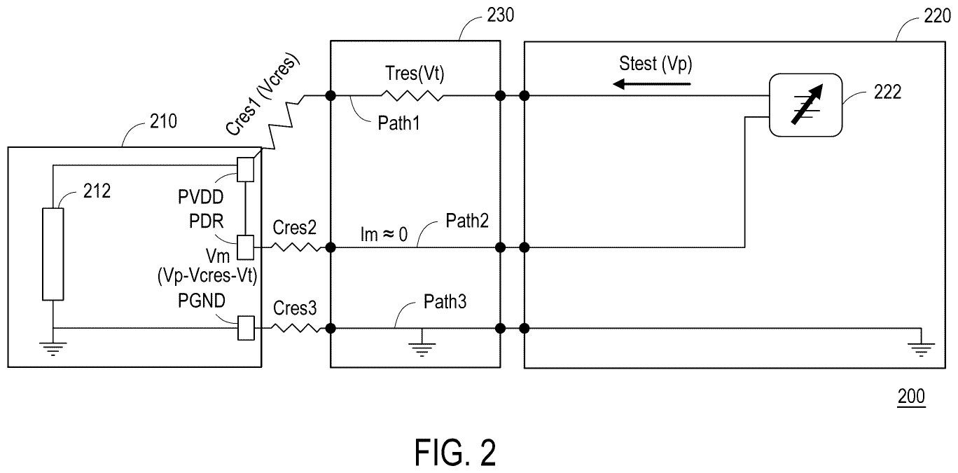

The following is another example to illustrate the chip test system in the disclosure. Referring to FIG. 2, a chip test system 200 includes a memory chip 210, a test device 220, and a test interface 230. As shown in FIG. 2, the memory chip 210 has a power pad PVDD, a driver pad PDR coupled to the power pad PVDD, and a grounding pad PGND. The grounding pad PGND is, for example, a pad configured to be coupled to a ground potential. A material of the grounding pad PGND is also a metal material, such as aluminum, aluminum alloy, or a combination thereof. The power pad PVDD, the driver pad PDR, and the grounding pad PGND may be interconnected with a metal circuit layer in the memory chip 210.

The test device 220 may be configured to provide the test signal Stest. The test interface 230 is coupled between the memory chip 210 and the test device 220, and in addition to providing the first signal transmission path Path1 and the second signal transmission path Path2, it also provides a third signal transmission path Path3. The third signal transmission path Path3 is coupled between the grounding pad PGND and the test device 220 and coupled to the ground potential. There are the first contact impedance Cres1 on the first signal transmission path Path1, the second contact impedance Cres2 on the second signal transmission path Path2, and third contact impedance Cres3 on the third signal transmission path Path3.

In FIG. 2, there is also transmission impedance Tres on the first signal transmission path Path1. The transmission impedance Tres is equivalent to the loss when the test signal Stest is transmitted through the test interface 230. In addition, the memory chip 210 includes an internal load 212. The internal load 212 is coupled between the power pad PVDD and the ground potential. The internal load 212 is, for example, any electronic element or device and apparatus on a circuit that consumes active power in the memory chip 210, and the disclosure is not limited thereto.

In this embodiment, the test device 220 includes a programmable power supply (PPS) 222. The programmable power supply 222 is coupled to the first signal transmission path Path1 and the second signal transmission path Path2 and may be configured to generate the test signal Stest. In the specific test mode, the programmable power supply 222 may set the initial test voltage value Vp of the test signal Stest to be the same as the target voltage value corresponding to the current test mode. The programmable power supply 222 may transmit the test signal Stest to the power pad PVDD of the memory chip 210 through the first signal transmission path Path1. The test signal Stest transmitted to the power pad PVDD will generate the voltage drop Vores and a voltage drop Vt respectively according to the first contact impedance Cres1 and the transmission impedance Tres. Therefore, the voltage received on the power pad PVDD is the test voltage value Vp minus the voltage drops Vores and Vt. The monitor voltage Vm generated by the driver pad PDR will also be equal to the test voltage value Vp minus the voltage drops Vcres and Vt.

Furthermore, the programmable power supply 222 may receive the monitor voltage Vm through the second signal transmission path Path2. Since the monitor current Im on the second signal transmission path Path2 is substantially 0 (equal to or almost close to 0), the second contact impedance Cres2 on the second signal transmission path Path2 will not cause the voltage drop. Therefore, the test device 220 may accurately obtain the monitor voltage Vm.

The programmable power supply 222 may compare the monitor voltage Vm with the target voltage value. When the monitor voltage Vm is less than the target voltage value, the programmable power supply 222 may increase the test voltage value Vp of the test signal Stest, thereby compensating for the voltage drops Vcres and Vt caused by the first contact impedance Cres1 and the transmission impedance Tres, so that the voltage value of the test signal Stest transmitted to the power pad PVDD is equal to or close to the target voltage value. In some embodiments, the programmable power supply 222 may repeatedly increase the test voltage value Vp of the test signal Stest until the monitor voltage Vm is equal to or close to the target voltage value.

Through the above structure, when the test device 220 tests the memory chip 210, the loss (the voltage drop) suffered by the test signal Stest may be appropriately compensated through a feedback loop formed by the second signal transmission path Path2 to ensure that the voltage value of the test signal Stest transmitted to the power pad PVDD is equal to or close to the target voltage value.

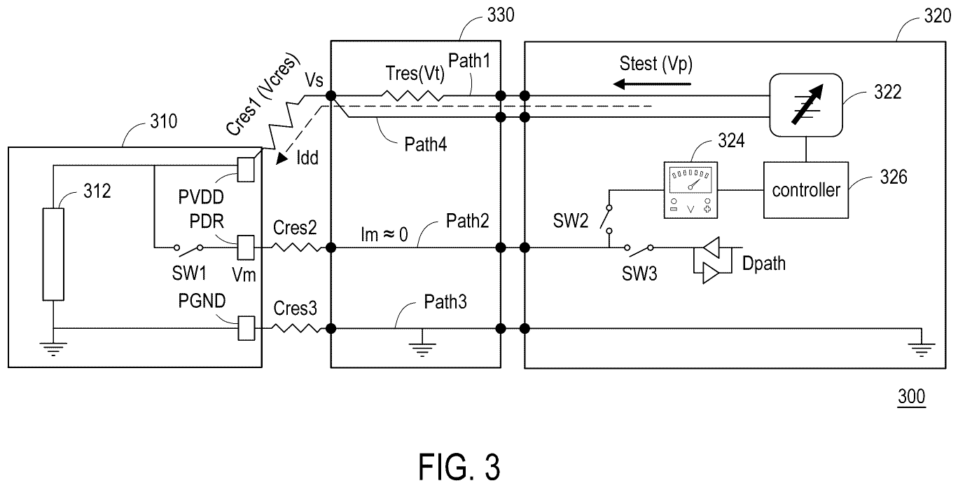

The following is another example to illustrate the chip test system in the disclosure. Referring to FIG. 3, a chip test system 300 includes a memory chip 310, a test device 320, and a test interface 330. As shown in FIG. 3, the memory chip 310 has the power pad PVDD, the driver pad PDR, and the grounding pad PGND. The power pad PVDD, the driver pad PDR, and the grounding pad PGND may be interconnected with a metal circuit layer in the memory chip 310. In addition, the memory chip 310 includes a first switch element SW1. The first switch element SW1 is coupled between the power pad PVDD and the driver pad PDR.

The test device 320 may be configured to provide the test signal Stest. The test interface 330 is coupled between the memory chip 310 and the test device 320, and provides the first signal transmission path Path1, the second signal transmission path Path2, and the third signal transmission path Path3. There are the first contact impedance Cres1 and the transmission impedance Tres on the first signal transmission path Path1, the second contact impedance Cres2 on the second signal transmission path Path2, and the third contact impedance Cres3 on the third signal transmission path Path3. In addition, the memory chip 310 includes an internal load 312. The internal load 312 is coupled between the power pad PVDD and the ground potential.

In this embodiment, the test device 320 includes a programmable power supply 322, a precise measurement unit 324, and a controller 326. The programmable power supply 322 is coupled to the first signal transmission path Path1. The programmable power supply 322 may be configured to generate the test signal Stest, and may measure a test current Idd flowing through the first signal transmission path Path1. As shown in FIG. 3, the test current Idd may flow to the internal load 312 through the first signal transmission path Path1. The programmable power supply 322 may further obtain a sensing voltage Vs of an output end of the test interface 330 on the first signal transmission path Path1 through a fourth signal transmission path Path4.

The precise measurement unit (PMU) 324 is coupled to the second signal transmission path Path2. The precise measurement unit 324 may be configured to measure the monitor voltage Vm generated by the driver pad PDR through the second signal transmission path Path2, which is considered to be equal to the voltage value of the test signal Stest transmitted to the power pad PVDD.

The controller 326 is, for example, a central processing unit, other programmable general-purpose or special-purpose microprocessors, a digital signal processor, a programmable controller, an application-specific integrated circuit, a programmable logic device, or other similar devices or a combination of these devices. In addition, the controller 326 may also be a hardware circuit designed through a hardware description language or any other design method of a digital circuit well known to those skilled in the art and implemented through a field programmable gate array or a complex programmable logic device. The controller 326 is coupled to the programmable power supply 322 and the precise measurement unit 324. In addition, the test device 320 further includes a second switch element SW2 and a third switch element SW3. The second switch element SW2 is coupled between the precise measurement unit 324 and the second signal transmission path Path2. The third switch element SW3 is coupled between the second signal transmission path Path2 and a transmission path Dpath of other driving signals (e.g., a clock enable signal CKE, etc.). In this way, an original built-in signal channel may be used to measure the monitor voltage Vm through switching of the switch elements to reduce a chip area.

In this embodiment, the controller 326 may be configured to set the test signal Stest through the programmable power supply 322 in the specific test mode, and set the initial test voltage value Vp of the test signal Stest to be the same as the target voltage value corresponding to the current test mode. Furthermore, the controller 326 may control the programmable power supply 322 according to the monitor voltage Vm, the first contact impedance Cres, and the test current Idd to adjust the test voltage value Vp of the test signal Stest.

Specifically, in the test mode, the memory chip 310 may be set to a state corresponding to the current test mode, and when the memory chip 310 starts to be tested, the controller 326 turns on the first switch element SW1 and the second switch element SW2, and turns off the third switch element SW3.

Then, the controller 326 may control the programmable power supply 322 to generate the test signal Stest with the same target voltage value corresponding to the current test mode on the first signal transmission path Path1. Furthermore, the programmable power supply 322 may further measure the test current Idd flowing through the first signal transmission path Path1.

The controller 326 may obtain the current monitor voltage Vm from the precise measurement unit 324, and calculate an impedance value of the first contact impedance Cres1. Specifically, the controller 326 may obtain the current monitor voltage Vm and the test current Idd from the precise measurement unit 324, obtain the sensing voltage Vs of the output end of the test interface 330 on the first signal transmission path Path1 from the programmable power supply 322, and divide a difference of the sensing voltage Vs minus the monitor voltage Vm by the test current Idd to calculate the impedance value of the first contact impedance Cres1.

Then, the controller 326 may determine whether a difference of the monitor voltage Vm minus the target voltage value is less than or equal to a voltage threshold value or whether the number of adjustments to the test voltage value Vp is greater than a number threshold value. Specifically, the controller 326 may first determine whether the difference of the monitor voltage Vm minus the target voltage value is less than or equal to the voltage threshold value. If yes, it means that the voltage value of the test signal Stest transmitted to the power pad PVDD has met requirements for the current test mode. At this time, the controller 326 may turn off the first switch element SW1 and the second switch element SW2, and turn on the third switch element SW3 to stop the measurement of the monitor voltage Vm, and allow the test device 320 to continue testing the memory chip 310.

If not, the controller 326 may determine whether the number of adjustments to the test voltage value Vp is greater than the number threshold value (e.g., 5 times). If yes, it means that the number of adjustments has exceeded a limit, and the test voltage value Vp will no longer be adjusted. At this time, the controller 326 may turn off the first switch element SW1 and the second switch element SW2, and turn on the third switch element SW3 to stop the measurement of the monitor voltage Vm, and allow the test device 320 to continue testing or stop testing the memory chip 310 depending on situations.

If not, it means that the difference of the monitor voltage Vm minus the target voltage value is not less than or equal to the voltage threshold value, and the number of adjustments to the test voltage value Vp is not greater than the number threshold value. At this time, the controller 326 may multiply the calculated impedance value of the first contact impedance Cres1 by the measured current test current Idd to calculate an adjustment amount used to adjust the test voltage value Vp, and increase the test voltage value Vp of the test signal Stest by the calculated adjustment amount through the programmable power supply 322.

After increasing the test voltage value Vp by the calculated adjustment amount, the monitor voltage Vm and the test current Idd will also change accordingly. The controller 326 may measure the current monitor voltage Vm and test current Idd again, and continue determining whether a difference of the monitor voltage Vm minus the target voltage value is less than or equal to a voltage threshold value. In addition, the controller 326 may repeatedly update the adjustment amount in the same calculation method as above according to the current monitor voltage Vm and test current Idd, and increase the test voltage value Vp of the test signal Stest by the updated adjustment amount until the difference of the monitor voltage Vm minus the target voltage value is less than or equal to the voltage threshold value, or the number of adjustments is greater than the number threshold value. It should be noted that those skilled in the art may set the above voltage threshold value and number threshold value according to actual accuracy requirements thereof.

Through this embodiment, when the test device 320 tests the memory chip 310, the original built-in signal channel may be used to measure the monitor voltage Vm, and the programmable power supply 322 and the precise measurement unit 324 of the test device 320 may also be used to appropriately compensate for the loss (the voltage drop) suffered by the test signal Stest, so as to reduce the test cost.

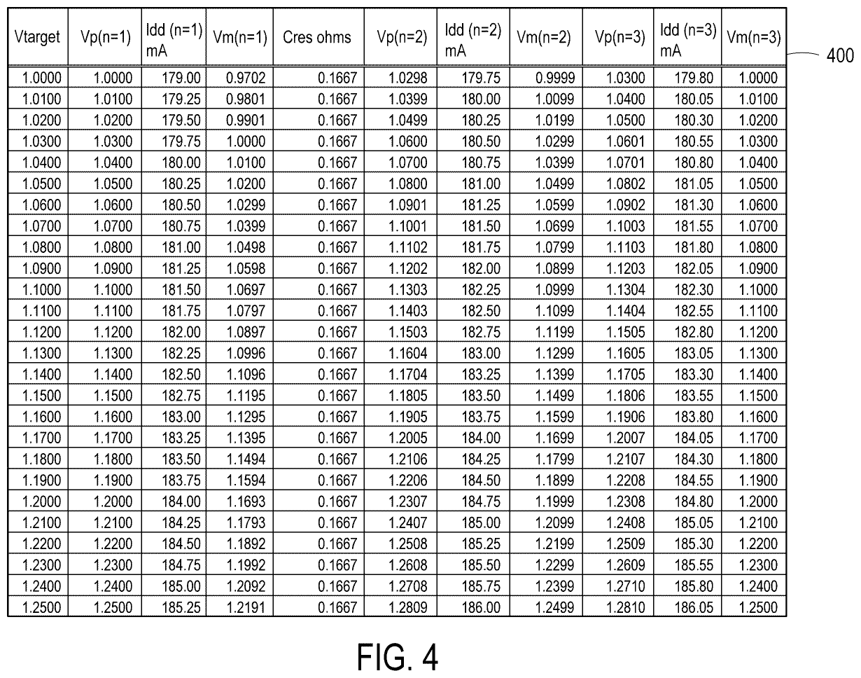

In one embodiment, the controller 326 may collect data of the test voltage value Vp, the monitor voltage Vm, the first contact impedance Cres1, and the test current Idd in a process of adjusting the test voltage value Vp for multiple target voltage values Vtarget corresponding to the test modes to establish a truth table. Referring to FIG. 4, in a truth table 400, the recorded target voltage values Vtarget are listed on the left, and the data of the test voltage value Vp, the monitor voltage Vm, the first contact resistance Cres1, and the test current Idd in the adjustment process are recorded in an order of the number of adjustments (n) to the test voltage value Vp. In this way, when the memory chip 310 is tested using the target voltage values Vtarget that has been recorded in the truth table 400, the appropriate test voltage value Vp may be found from the truth table 400 to quickly adjust the test signal Stest.

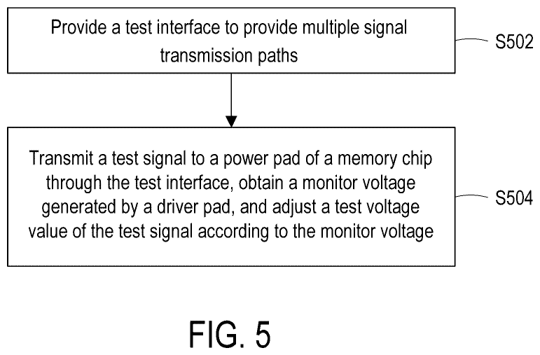

Referring to FIG. 5, a chip test method in this embodiment includes the following steps. A test interface is provided to provide multiple signal transmission paths (step S502). Then, through the test interface, a test signal is transmitted to a power pad of a memory chip, a monitor voltage generated by a driver pad is obtained, and a test voltage value of the test signal is adjusted according to the monitor voltage (step S504). The chip test method in this embodiment may be executed by using the chip test system shown in FIGS. 1 to 3, and the relevant description will not be repeated here.

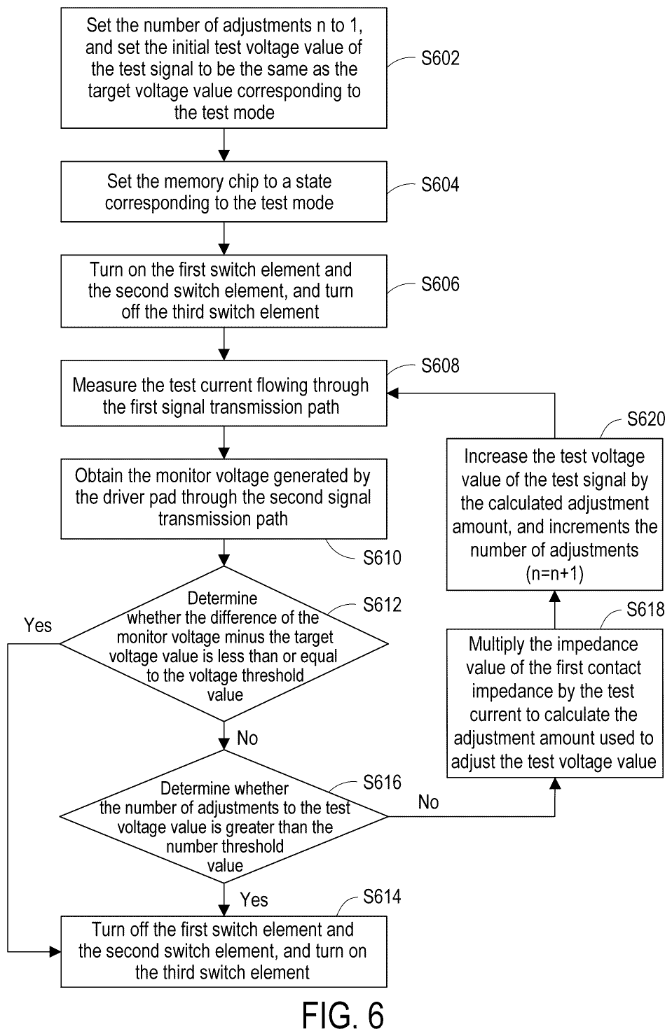

Referring to FIGS. 3 and 6 together, the chip test method according to another embodiment of the disclosure is applicable to the chip test system 300 in FIG. 3. Hereinafter, each of steps of an erasing method according to the embodiment of the disclosure is described with reference to various elements in the chip test system 300.

In step S602, the controller 326 sets the number of adjustments (n) to 1, and sets the initial test voltage value Vp of the test signal Stest to be the same as the target voltage value corresponding to the test mode. In step S604, the memory chip is set to a state corresponding to the test mode. In step S606, the controller 326 turns on the first switch element SW1 and the second switch element SW2, and turns off the third switch element SW3.

Next, in step S608, the programmable power supply 322 measures the test current Idd flowing through the first signal transmission path Path1. In step S610, the controller 326 obtains the monitor voltage Vm generated by the driver pad PDR through the second signal transmission path Path2 through the precise measurement unit 324. In step S612, the controller 326 determines whether the difference of the monitor voltage Vm minus the target voltage value is less than or equal to the voltage threshold value. If yes, the controller 326 turns off the first switch element SW1 and the second switch element SW2, and turns on the third switch element SW3 (step S614) to continue testing. If not, the controller 326 determines whether the number of adjustments to the test voltage value Vp is greater than the number threshold value (step S616).

If the number of adjustments to the test voltage value Vp is greater than the number threshold value, the controller 326 turns off the first switch element SW1 and the second switch element SW2, and turns on the third switch element SW3 (step S614) to continue testing or stop testing.

If the number of adjustments to the test voltage value Vp is not greater than the number threshold value, the controller 326 multiplies the impedance value of the first contact impedance Cres1 by the test current Idd to calculate the adjustment amount used to adjust the test voltage value Vp (step S618). Next, in step S620, the programmable power supply 322 increases the test voltage value Vp of the test signal Stest by the calculated adjustment amount, and increments the number of adjustments (n=n+1).

Then, returning to step S608, the controller 326 repeatedly updates the adjustment amount in the same calculation method as above according to the current monitor voltage Vm and test current Idd, and increases the test voltage value Vp of the test signal Stest by the updated adjustment amount until the difference of the monitor voltage Vm minus the target voltage value is less than or equal to the voltage threshold value, or the number of adjustments is greater than the number threshold value. For implementation details of the above steps S602, S604, S606, S608, S610, S612, S614, S616, S618, and S620, the relevant description in FIG. 3 may be referred, which will not be repeated in the following.

In addition, the chip test system and method according to the disclosure may be applied to a low-power memory and a vertically stacked chip or KGD, and may be applied to applications in the fields of artificial intelligence, electric vehicles, mobile devices, etc. However, the disclosure is not limited thereto.

Based on the above, when the memory chip is tested, the chip test system in the disclosure may appropriately compensate for the loss (the voltage drop) of the test signal due to the contact impedance through the feedback loop formed by the driver pad on the memory chip, so as to ensure that the voltage value of the test signal transmitted to the power pad is equal to or close to the target voltage value. In this way, it is possible to avoid reduction of test accuracy due to the voltage drop, increase tolerance for the contact impedance, while maintaining test quality and productivity, and reducing the test cost. Therefore, the disclosure provides a green semiconductor technology.

What is claimed is:

1. A chip test system, comprising:
a memory chip having a power pad and a driver pad coupled to the power pad;
a test device configured to provide a test signal; and
a test interface coupled between the memory chip and the test device to provide a plurality of signal transmission paths, wherein the signal transmission paths comprise a first signal transmission path having first contact impedance, and a second signal transmission path having second contact impedance,
wherein the test device comprises a programmable power supply coupled to the first signal transmission path to generate the test signal and measure a test current flowing through the first signal transmission path, and is configured to transmit the test signal to the power pad of the memory chip through the first signal transmission path, obtain a monitor voltage generated by the driver pad through the second signal transmission path, and adjust a test voltage value of the test signal by controlling the programmable power supply according to the monitor voltage, the first contact impedance, and the test signal.

2. The chip test system according to claim 1,
wherein the test signal transmitted to the power pad generates a voltage drop according to the first contact impedance, and a monitor current on the second signal transmission path is substantially 0.

3. The chip test system according to claim 1, wherein the programmable power supply coupled to the second signal transmission path to receive the monitor voltage.

4. The chip test system according to claim 1, wherein the programmable power supply compares the monitor voltage with a target voltage value, and when the monitor voltage is less than the target voltage value, the programmable power supply increases the test voltage value of the test signal.

5. The chip test system according to claim 4, wherein an initial test voltage value of the test signal is set to be the same as the target voltage value.

6. The chip test system according to claim 1, wherein the test device further comprises:
a precise measurement unit coupled to the second signal transmission path to measure the monitor voltage; and
a controller coupled to the programmable power supply and the precise measurement unit to set the test signal through the programmable power supply in a test mode, set the initial test voltage value of the test signal to be the same as a target voltage value corresponding to the test mode, and control the programmable power supply according to the monitor voltage, the first contact impedance, and the test current to adjust the test voltage value of the test signal.

7. The chip test system according to claim 6, wherein the memory chip comprises a first switch element, the first switch element is coupled between the power pad and the driver pad, the test device further comprises a second switch element and a third switch element, the second switch element is coupled between the precise measurement unit and the second signal transmission path, the third switch element is coupled between the second signal transmission path and a driving signal transmission path, and when the memory chip starts to be tested, the controller turns on the first switch element and the second switch element, and turns off the third switch element.

8. The chip test system according to claim 6, wherein the controller obtains a sensing voltage of an output end of the test interface on the first signal transmission path from the programmable power supply, and divides a difference of the sensing voltage minus the monitor voltage by the test current to calculate an impedance value of the first contact impedance.

9. The chip test system according to claim 8, wherein the controller determines whether a difference of the monitor voltage minus the target voltage value is less than or equal to a voltage threshold value or whether a number of adjustments to the test voltage value is greater than a number threshold value,
if not, the controller multiplies the impedance value by the test current to calculate an adjustment amount used to adjust the test voltage value, and increases the test voltage value of the test signal by the adjustment amount through the programmable power supply,
the controller repeatedly updates the adjustment amount according to the current monitor voltage and the test current and increases the test voltage value of the test signal by the updated adjustment amount until the difference of the monitor voltage minus the target voltage value is less than or equal to the voltage threshold value, or the number of adjustments is greater than the number threshold value.

10. The chip test system according to claim 1, wherein the memory chip comprises an internal load, and the internal load is coupled between the power pad and a ground potential.

11. The chip test system according to claim 1, wherein the memory chip further has a grounding pad, the signal transmission paths further comprise a third signal transmission path having third contact impedance, and the third signal transmission path is coupled between the grounding pad and the test device, and is coupled to a ground potential.

12. The chip test system according to claim 6, wherein the controller collects data of the test voltage value, the monitor voltage, the first contact impedance, and the test current in a process of adjusting the test voltage value for a plurality of target voltage values corresponding to a plurality of test modes to establish a truth table.

13. A chip test method, suitable for a memory chip having a power pad and a driver pad coupled to the power pad, wherein the chip test method comprises:
providing a test interface to provide a plurality of signal transmission paths, wherein the signal transmission paths comprise a first signal transmission path having first contact impedance, and a second signal transmission path having second contact impedance;
generating a test signal and measure a test current flowing through the first signal transmission path by a programmable power supply coupled to the first signal transmission path;
transmitting the test signal to the power pad of the memory chip through the first signal transmission path;
obtaining a monitor voltage generated by the driver pad through the second signal transmission path; and
adjusting a test voltage value of the test signal by controlling the programmable power supply according to the monitor voltage, the first contact impedance, and the test signal.

14. The chip test method according to claim 13, wherein the test signal transmitted to the power pad generates a voltage drop according to the first contact impedance.

15. The chip test method according to claim 13, wherein a monitor current on the second signal transmission path is substantially 0.

16. The chip test method according to claim 15, wherein adjusting the test voltage value of the test signal comprises:
comparing the monitor voltage with a target voltage value, and when the monitor voltage is less than the target voltage value, increasing the test voltage value of the test signal.

17. The chip test method according to claim 13, further comprising:
setting the test signal in a test mode, and setting the initial test voltage value of the test signal to be the same as a target voltage value corresponding to the test mode.

18. The chip test method according to claim 13, wherein adjusting the test voltage value of the test signal according to the monitor voltage, the first contact impedance, and the test current comprises:
obtaining a sensing voltage of an output end of the test interface on the first signal transmission path; and
dividing a difference of the sensing voltage minus the monitor voltage by the test current to calculate an impedance value of the first contact impedance.

19. The chip test method according to claim 18, wherein adjusting the test voltage value of the test signal according to the monitor voltage, the first contact impedance, and the test current further comprises:
determining whether a difference of the monitor voltage minus the target voltage value is less than or equal to a voltage threshold value or whether a number of adjustments to the test voltage value is greater than a number threshold value,
if not, multiplying the impedance value by the test current to calculate an adjustment amount used to adjust the test voltage value, and increasing the test voltage value of the test signal by the adjustment amount; and
repeatedly updating the adjustment amount according to the current monitor voltage and the test current and increasing the test voltage value of the test signal by the updated adjustment amount until the difference of the monitor voltage minus the target voltage value is less than or equal to the voltage threshold value, or the number of adjustments is greater than the number threshold value.

20. A chip test system, comprising:
a memory chip having a power pad and a driver pad coupled to the power pad;
a test device configured to provide a test signal; and
a test interface coupled between the memory chip and the test device to provide a plurality of signal transmission paths, wherein the signal transmission paths comprise a first signal transmission path having first contact impedance, and a second signal transmission path having second contact impedance,
wherein the test device is configured to transmit the test signal to the power pad of the memory chip through the first signal transmission path, obtain a monitor voltage generated by the driver pad through the second signal transmission path, and adjust a test voltage value of the test signal according to the monitor voltage,
wherein the test device comprises:
a precise measurement unit coupled to the second signal transmission path to measure the monitor voltage; and
a switch element coupled between the precise measurement unit and the second signal transmission path, and when the memory chip starts to be tested, the switch element is turned on.
